(19) United States
(12) Patent Application Publication
(10) Pub. No.: US 2006/0043882 A1
(43) Pub. Date: Mar. 2, 2006

(54) Method and apparatus for providing a substrate coating having predetermined resistivity, and uses therefor

(75) Inventors: Xu Shi, Singapore (SG); Li Kang Cheah, Singapore (SG)

Correspondence Address: VOLPE AND KOENIG, P.C., UNITED PLAZA, SUITE 1600, 30 SOUTH 17TH STREET, PHILADELPHIA, PA, 19103, US

(73) Assignee: Nanofilm Technologies International PTE LTD, Singapore (SG)

(21) Appl. No.: 11/200,908

(22) Filed: Aug. 10, 2005

(30) Foreign Application Priority Data
Aug. 27, 2004 (GB) 0419177.1

(51) Int. Cl. H05B 33/14; H05B 33/00; C23C 16/26; C23C 16/32

(52) U.S. Cl. 313/504; 427/249.1; 313/506

(57) ABSTRACT

A method and apparatus for providing a substrate coating having a predetermined resistivity is described. The method comprises the steps of providing a substrate to be coated in a vacuum chamber, creating a plasma in the chamber, and depositing ions of the plasma on the substrate to form a ta-C substrate coating. The coating “step is stopped when the ta-C substrate coating has the predetermined resistivity. The predetermined resistivity is 10⁵-10¹⁰ Ωcm, and preferably about 10⁶ Ωcm. The substrate may be biased during the method to aid in arriving at the predetermined resistivity. The coating may be employed to reduce the risk of, or prevent electrostatic discharge to or from the substrate, or to provide a seed layer to improve adhesion between the substrate a further coating. Also described are coatings having predetermined resistivities.

### FIELD OF THE INVENTION

The present invention relates to a method of providing a substrate coating having a predetermined resistivity and in particular to methods and apparatus for providing antistatic discharge and/or seed layer coatings on a substrate surface. As will be understood by the skilled addressee, the invention is not limited to such uses.

### BACKGROUND

Undesired electrostatic discharge (ESD) can damage sensitive electronic and related components. ESD may be sourced from people, equipment in electronics manufacture, and through the general use of electronics equipment. Examples of components which may be damaged include, but are not limited to, memory media and equipment for the manufacturing or reading thereof, fingerprint and touch sensor or similar sensors having electrically exposed active circuits, integrated circuit (1C) packages and components thereof, and so on. An example of an ESD source is staff assembling electronic components, where static electricity is generated by their general body movement. This static electricity may then be discharged through their finger to the component they are handling, and damage the component. In another example, static electricity may build up and discharge between a reader arm head and disk of a hard disk drive.

Several methods are employed to reduce or prevent ESD in electronics manufacture. For example, manufacturing staff may wear grounded wrist bands to draw static electricity safely from their body. Also, grounded antistatic mats may be provided at entrances to sensitive assembly areas, so that staff discharge static electricity into the grounded mat when entering the assembly area.

Another example of ESD prevention includes coating of sensitive components, or equipment for use with sensitive components, with a coating having low resistivity properties. Such coatings are typically applied “wet”, for example by spraying a liquid emulsion onto the component and allowing it to dry. Problems associated with wet applied coatings include poor adhesion with the component to be coated and difficulty in applying an even coat. Since the resistivity properties are at least in part related to the thickness of the coat, an uneven coat results in the coating having a resistivity of an undesirable variability. Also, wet applied coatings are most reliable and consistent only when relatively thickly coated. However, thick coatings are not desirable in precision engineering, as they may undesirably alter the outer dimensions of the coated product.

### SUMMARY

It is an object of at least one of preferred embodiments of the invention to overcome or ameliorate at least one of the problems of the prior art.

According to a first aspect of the invention there is provided a method of providing a substrate coating having a predetermined resistivity, comprising the steps of:
providing a substrate to be coated in a vacuum chamber;
creating a carbon plasma in the chamber; and
1. depositing ions of the plasma on the substrate to form a tetrahedral amorphous carbon (ta-C) substrate coating.

ta-C coatings are used for their hardness, wear and scratch resistance properties, and these properties are also present as a result of using the present invention. However, by using the novel and inventive method of the present invention, it is also possible to achieve relatively accurate resistivity properties in coated substrates which increases or at least enhances the uses of ta-C as a substrate coating. Examples of potential uses are described in more detail below.

Preferably, the predetermined resistivity is 10⁵-10⁹ Ωcm, ranging between an insulator and a conductor. Also preferably, the predetermined resistivity is 2×10⁵ to 10⁷ Ωcm, or 4×10⁵ to 5×10⁶ Ωcm. More preferably the predetermined resistivity is about 10⁶ Ωcm. The coating step is stopped when the ta-C substrate coating has the predetermined resistivity. Preferably the resistivity is controlled by biasing the substrate during the deposition step, preferably at −100V to −3000V, and more preferably −500V to −1500V. Preferably the coating is 5-80 nm in thickness, and more preferably 20-50 nm. The step of biasing the substrate improves the accuracy of achieving the predetermined resistivity.

Preferably, the time duration of the deposition is 50 s to 300 s.

Parameters affecting the predetermined resistivity include one or more of the thickness of the coating, the amount of bias applied to the substrate during coating, the type and volume of gas present in the chamber during the deposition process, and duration of the deposition step. The step of stopping may be determined using a predetermined elapsed time, or using a feedback sensing device to measure the resistivity of the coating such that the stopping step is employed when the predetermined resistivity is achieved.

Preferably, the deposition step is carried out by apparatus in communication with the chamber, the apparatus comprising a carbon target and a power source for supplying power to the target. In an alternative embodiment, a second deposition step is carried out by a second apparatus in communication with the chamber, the second apparatus comprising a metal target and a power source for supplying power to the metal target, wherein the ta-C substrate coating comprises metal provided by a plasma from the metal target.

Preferably, the chamber is evacuated prior to the deposition step, and the substrate is cleaned in the vacuum chamber after the chamber is evacuated and prior to the deposition step. Also preferably, the chamber is evacuated prior to the deposition step, and the substrate is cleaned in the vacuum chamber after exposure to the plasma and prior to a step of repressurising the chamber.

Preferably, the deposition apparatus is a filtered cathodic vacuum arc (FCVA) apparatus.

Preferably, the method comprises the step of introducing a gas into the vacuum chamber during the deposition step such that the coating on the substrate is a compound of the gas and ta-C. Preferably the gas is one of nitrogen or argon. Alternatively, the gas may include, or be one of ammonia, oxygen, methane or ethane (ethylene). The pressure in the chamber during deposition is preferably 0.05 mTorr to 1.0 mTorr, and more preferably 0.2 mTorr to 0.8 mTorr.

Preferably, the substrate is one of or a portion or component of: a fingerprint sensor; an electronic package having an exposed active circuit; a touch screen panel; memory media; a digital memory reader component (eg a flexible circuit on the suspension arm of a hard disk drive); an integrated circuit (1C) package, or component thereof; an 1C wafer tray and holder; a layer of an organic light emitting diode; or a flash memory device (eg Secure Digital card or Compact Flash card) or associated reader.

According to another aspect of the invention there is provided apparatus for providing a coating of ta-C on a substrate, the apparatus comprising:

a vacuum chamber for housing the substrate to be coated;

means for creating a carbon plasma in the chamber; and

control means for actuating the plasma creating means, and then for stopping the plasma creating means when the ta-C substrate coating has a predetermined resistivity.

Preferably, the predetermined resistivity is 10⁵-10⁹ Ωcm. Also preferably, the predetermined resistivity is 2×10⁵ to 10⁷ Ωcm, or 4×10⁵ to 5×10⁶ Ωcm. More preferably the predetermined resistivity is about 10⁶ Ωcm. Also preferably, the control means is configured to stop the plasma creating means when the coating is 5-80 nm in thickness, and more preferably when the coating is 20-50 nm in thickness. Alternatively, the control means is configured to stop the plasma creating means when a feedback mechanism registers that the predetermined resistivity has been realized.

Preferably, the apparatus also comprises substrate biasing means for biasing the substrate when the plasma creating means is actuated. Preferably, the substrate biasing means is configured to bias the substrate at −100V to −3000V, and more preferably −500V to −1500V.

Preferably, the plasma creating means is a filtered cathodic vacuum arc apparatus.

According to another aspect of the invention there is provided a substrate comprising a ta-C coating having a predetermined resistivity of 10⁵-10⁹ Ωcm. Also preferably, the predetermined resistivity is 2×10⁵ to 10⁷ Ωcm, or 4×10⁵ to 5×10⁶ Ωcm. More preferably the predetermined resistivity is about 10⁶ Ωcm.

Preferably, the substrate comprises a ta-C coating having a predetermined resistivity of 10⁶ Ωcm.

According to another aspect of the invention there is provided a ta-C coating for a substrate, the coating having a predetermined resistivity of 10⁵-10⁹ Ωcm. Also preferably, the predetermined resistivity is 2×10⁵ to 10⁷ Ωcm, or 4×10⁵ to 5×10⁶ Ωcm. More preferably the predetermined resistivity is about 10⁶ Ωcm.

Preferably, the coating of the above two aspects is provided by the above described method aspect.

As will be understood, the term “ta-C coating” throughout the specification means tetrahedral amorphous carbon coating which may include other allotropes of carbon, or other elements or compounds. The other elements or compounds may include compounds resulting from gas present in the chamber during the deposition step. Alternatively, if a second target is used as described above, the ta-C coating may also include elements or compounds from the second target. The carbon content of the ta-C coating is typically >30 mol %.

According to another aspect of the present invention there is provided an organic light emitting diode (OLED) display comprising a plurality of stacked layers, the layers including, in order of stacking:

a first transparent polymer layer;

a ta-C seed layer having a predetermined resistivity;

a transparent electrode film layer;

an OLED layer;

one or more metallic layers; and

a second polymer layer.

Advantageously, the OLED is flexible, compared to glass based OLEDs, and the use of the ta-C layer improves the adhesion between the polymer layer and the electrode film layer. Also advantageously, the ta-C layer prevents permeation of air or water passing through the polymer layer to the metallic layers, and thus prevents their oxidation.

Preferably, the ta-C layer is provided by the above described method aspect.

Preferably, the ta-C layer is 10-50 Å in thickness. Also, the resistivity of the ta-C layer is preferably 10⁵-10⁹ Ωcm.

Preferably, the polymer layer is polycarbonate, the transparent electrode film layer is one of ITO or ZnO, and the one or more metallic layers include Ca and Al. Also preferably, the OLED display comprises a second ta-C layer over the one or more metallic layers, the second ta-C layer being 20-500 Å.

According to another aspect of the invention there is provided a method of providing a coating on a substrate so as to reduce the risk of, or to prevent electrostatic discharge to or from the substrate, the method comprising the steps of:

providing a substrate to be coated in a vacuum chamber;

creating a carbon plasma in the chamber; and

depositing ions of the plasma on the substrate to form a tetrahedral amorphous carbon (ta-C) substrate coating having a predetermined resistivity.

Preferably, the deposition step is stopped when the predetermined resistivity is 10⁵-10⁹ Ωcm, and more preferably about 10⁶ Ωcm. Also preferably, the predetermined resistivity is 2×10⁵ to 10⁷ Ωcm, or 4×10⁵ to 5×10⁶ Ωcm. More preferably the predetermined resistivity is about 10⁶ Ωcm.

According to another aspect of the invention there is provided a method of providing a coating on a substrate so as to improve adhesion of a further coating on the substrate, the method comprising the steps of:

providing a substrate to be coated in a vacuum chamber;

creating a carbon plasma in the chamber; and

depositing ions of the plasma on the substrate to form a tetrahedral

amorphous carbon (ta-C) substrate coating having a predetermined resistivity.

Preferably, the deposition step is stopped when the predetermined resistivity is 10⁵-10⁹ Ωcm. Also preferably, the deposition step is stopped when the predetermined resistivity is 2×10⁵ to 10⁷ Ωcm, or 4×10⁵ to 5×10⁶ Ωcm. More preferably the deposition step is stopped when the predetermined resistivity is about 10⁶ Ωcm. In one embodiment, the substrate is a polymer and the further coating is a metal or a metal compound. Preferably, the substrate is polycarbonate and/or the metal compound is ITO or ZnO. Alternatively, the substrate is a metal or a metal compound and the further coating is a polymer.

### BRIEF DESCRIPTION OF THE DRAWINGS

Preferred embodiments of the invention will now be described, by way of example only, with reference to the accompanying drawings in which:

FIGS. 1 and 2 are schematic diagrams illustrating an embodiment of apparatus for providing the substrate coating of the invention;

FIGS. 3 to 4B illustrate several uses of an embodiment of the present invention; and

FIGS. 5 and 6 illustrate exploded schematic and magnified portion views of an OLED incorporating an embodiment of the present invention.

### DETAILED DESCRIPTION OF THE PREFERRED EMBODIMENTS

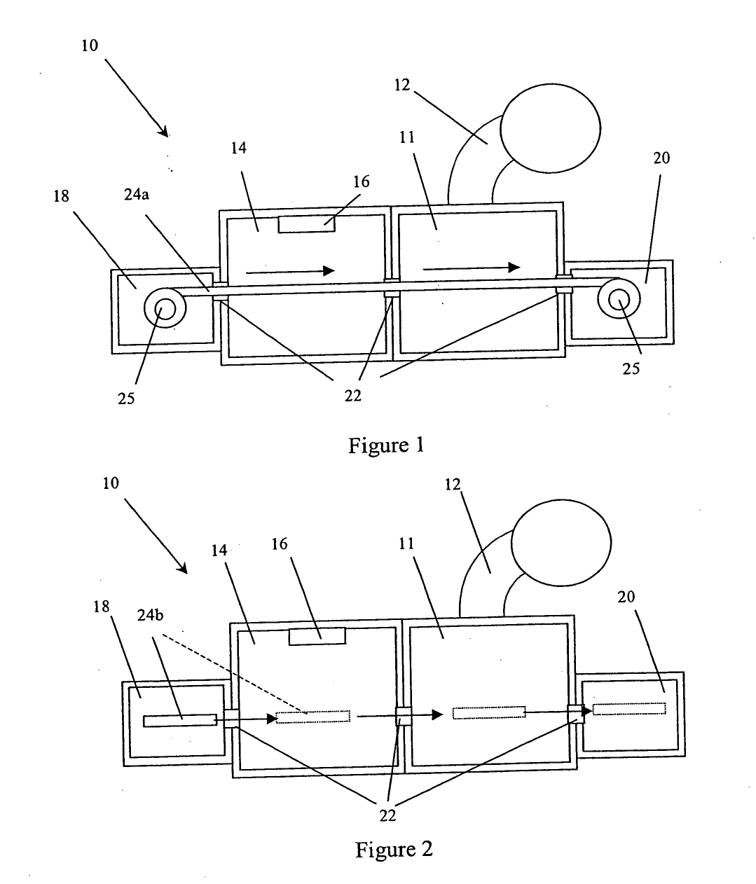

Referring to FIG. 1, a preferred embodiment of the present invention is a method of providing a substrate coating having a predetermined resistivity. The coating formed from the method is ta-C, or a ta-C compound as discussed above, being about 30 nm in thickness. The predetermined resistivity of the coating is approximately 10⁶ Ωcm.

The inventive coating can be used in several applications which may generally be described as antistatic discharge (ASD) coatings, and as seed layers for improving adhesion between adjacent layers. Properties of the coating also allow it to provide a secondary use as a barrier layer. Examples of the coating's use as ASD, seed and barrier layers are described in more detail below.

The preferred method of the present invention for providing a substrate coating having a predetermined resistivity is performed in an apparatus 10 comprising a vacuum chamber in the form of a coating chamber 11 in communication with means for creating a plasma in the chamber, in the form of a FCVA apparatus 12. The FCVA apparatus 12 comprises a graphite target, a power source for supplying power to the target, and an anode in a conventional arrangement. An example for how the FCVA provides a plasma is described in the applicant's International Patent Publication No. WO-A-96/26531. Whereas the preferred embodiment is arranged, for use with an FCVA apparatus, it will be understood that in alternative embodiments, the plasma may be provided by other types of physical vapor deposition apparatus, such as conventional apparatus which is wholly or partly within the chamber 11. However, it is preferred to use FCVA apparatus for its filtering capabilities to prevent macro-particles from coating the substrate surface.

The vacuum chamber also comprises, in communication with the coating chamber 11, a cleaning chamber 14 for cleaning the substrate surface prior to coating. This is achieved by use of an ion beam source 16 within the cleaning chamber 14. Feed and collection subchambers 18 and 20 are also provided in communication with the cleaning chamber 14 and vacuum chamber 11, respectively. The chambers 11, 14 and the subchambers 18, 20 are in communication with each other via narrow openings 22 which are sized to allow passage of the substrate therethrough.

Steps of the preferred method will now be described with reference to FIGS. 1 and 2, where like reference numerals denote like parts. In FIG. 1 the substrate 24a is a flexible material, such as a flexible circuit board, supplied in roll form, and in FIG. 2 the substrate 24b is in discrete units, such as integrated circuit (IC) packages. In both FIGS. 1 and 2, the method is continuous, where the substrate 24a, 24b is moved from the feed subchamber 20 through the chambers 14 and 11 and into the collection subchamber 20, via the narrow openings 22. In the method, the substrate 24a,b is provided or put into the system 10 at the feed subchamber 18, and the chambers 11, 14 and subchambers 18, 20 are evacuated to a pressure of about 1 μTorr. Argon is then introduced in to the vacuum chamber 11 to a pressure of about 300 82 Torr. The substrate 24a/b is moved through the opening 22 in to the cleaning chamber 14. The ion beam source 16 is actuated to clean the substrate's 24a,b surface prior to moving the substrate 24a,b into the coating chamber 11. The FCVA 12 is then actuated to provide a plasma of the graphite target, such that carbon ions coat the substrate surface as ta-C. The time interval for the coating of the substrate surface is controlled to between about 50 and 300 seconds. Furthermore, during the coating process, the substrate is biased to −800V. The inventors have found that by biasing the substrate, the desired resistivity of the coating can be achieved with greater accuracy than known methods. Once the coating has been applied to the desired thickness, the substrate 24a,b is moved from the coating chamber 11 to the collection subchamber 20. Once a predetermined amount of substrate roll 24a or number of substrate units 24b have been coated, the ion beam source 16 and FCVA are de-actuated and air is introduced into the chambers 11, 14 and subchambers 18, 20. When the pressure inside the chambers 11, 14 and subchambers 18,20 reaches atmospheric pressure, the coated substrate(s) 24a/b are then removed from the collection subchamber 20.

In the embodiment illustrated in FIG. 1, the substrate 24a is moved through the chambers and subchambers by driving rollers 26, whereas in the embodiment illustrated in FIG. 2, the substrate portions 24b are moved through the chambers and subchambers on a car or conveyor (not shown) by known methods.

In another alternative arrangement, a second FCVA source (not shown) is in communication with the coating chamber 11, and provides a plasma having metallic ions, to provide a resultant coating having a ta-C/metallic composition.

The inventors have found that the substrate coating resulting from the preferred method has surprisingly uniform properties which provide an improved anti-static discharge (ASD) coating when compared with “wet” applied ASD coatings, discussed in relation to the prior art above. Tests on substrate coatings provided by the preferred method have shown that the coatings have ±5% uniformity of thickness, ±10% repeatability of resistivity from one batch to the next, and that the resistivity can be controlled to be 10⁶ Ωcm ±5%. This level of tolerance is hot possible using known “wet” coat methods. Results of other standard tests have shown that the tribocharge of the coating at 1000V is <1 V, and the static decay is 0.4 s for 10% cutoff at 1000V. Furthermore, integrity testing has shown that the coating is still integral after 30 min in an ultrasonic bath. In contrast, thin “wet” applied coatings tend to lose integrity after about 1 min in an ultrasonic bath, due to poor adhesion when not applied relatively thickly. Also, the coating of the preferred embodiment has a relatively low stress of <1 GPa, relatively high density of >2.5 g/cm³, and relatively high hardness of about 50 GPa. Since the coating is applied at a relatively low temperature, (i.e. approximately room temperature) the coating process does not affect substrates susceptible to damage at elevated temperatures.

If it is desired to have a coating resistivity of more or less than 10⁶ Ωcm, one or more of the coating thickness, gas present during the coating process, the magnitude of biasing of the substrate, or duration of the coating process are altered during the coating process. In an alternative embodiment, a feedback sensing device is provided during the coating process to measure the resistivity of the coating, such that the coating process can be stopped when the coating reaches the predetermined resistivity as measured by the feedback sensing device.“

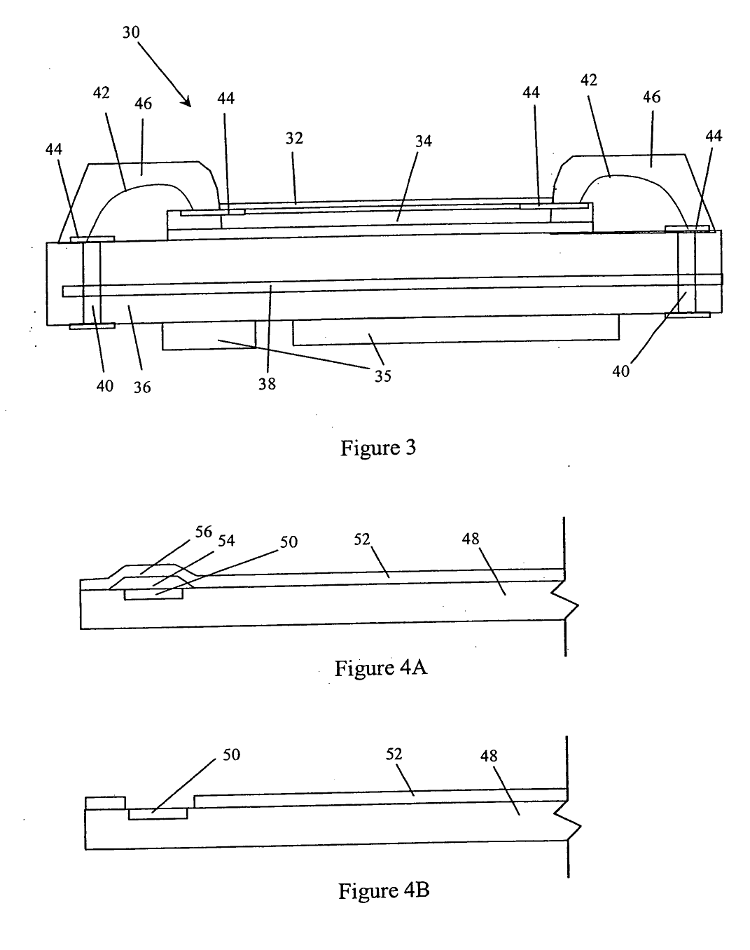

FIG. 3 illustrates an embodiment of the invention employed as an ASD coating. A ta-C coating 32 having a surface resistivity of about 10⁶ Ωcm is provided on a conventional fingerprint sensor 30 by the preferred method of the present invention. The fingerprint sensor 30 is basically an integrated circuit package having an active circuit 34 at a surface thereof which detects the touch of a user's finger and scans the finger for its print. For sake of completeness, other components of the fingerprint sensor 30 include active components 35 in electrical communication with the active circuit 34, a PCB 36, ground plane 38, through holes 40, wire bonds 42 between bond pads 44 and an epoxy mould 46 over the wire bonds 42. The touch surface of conventional fingerprint sensors is usually Si₃N₄, SiON or SiO₂, and typically has a resistivity of >10¹ Ωcm. Therefore, in practice, the user often discharges static electricity from their finger tip when touching the active circuit 34. If the ESD from the user is great enough, the active circuit and/or electrical components connected thereto can be irreparably damaged. By applying the coating 32 of the present invention to the surface of the sensor, the risk of ESD is reduced or prevented yet the coating still has sufficient conductivity to register the touch of the user's finger through the coating 32 to the active circuit 34.

As will be understood from the above example, the novel substrate coating may be used to protect from ESD other types of exposed active circuits, including touch sensitive display panels.

FIGS. 4A and 4B illustrate a method of coating an active circuit 48 prior to wire bonding, using the principles of the present invention in a conventional lithography process. In this example, the bonding pad 50 cannot be covered by the ta-C coating 52, or wire bonding will not be achieved. Therefore, a photoresist element 54 is placed on the bonding pad 50 prior to applying the substrate coating 52. FIG. 4A illustrates the active circuit 48 with applied ta-C coating 52 and photoresist element 54 between the coating 52 and the bonding pad 50. Once the ta-C substrate coating 52 is applied, a NaOH solution is used to strip the photoresist 54 and substrate coating portion 56 thereupon from the bonding pad 50. As illustrated in FIG. 4B, this results in the active circuit 48 being coated by the substrate coating 52, but with the bonding pad 50 being exposed.

In an alternative arrangement, the principles of the invention can also be used with known metal masking techniques. A metal mask is provided in a predetermined shape to cover predetermined sections (such as wire bond pads) of the active circuit, allowing uncovered sections to be exposed during the ta-C coating process. After coating, the mask is removed to reveal non-coated exposed portions.

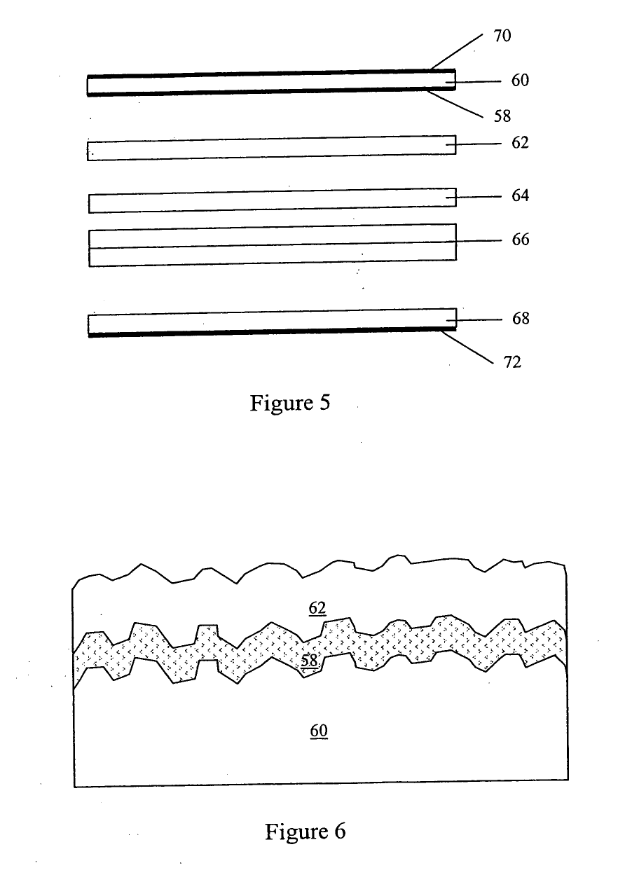

FIGS. 5 and 6 illustrate an alternative use for the invention relating to organic light emitting diode (OLED) displays, where the resistivity property of the coating allows the coating to be used as a seed layer to provide improved adhesion between two layers having very different resistance properties. Conventional OLEDs comprise several adjacent layers, including (in order) a first glass layer, a transparent electrode film (eg ITO, ZnO) deposited on a surface of the first glass layer, an organic OLED polymer, Ca and Al, and a second glass layer. As glass is brittle, current research is exploring the replacement of the glass layer with flexible, transparent polymers, such as polycarbonate. However, whereas the temperature when depositing the electrode film onto the glass layer can be relatively high, it must be lower when depositing onto the polycarbonate layer so as not to adversely affect the polycarbonate. Bonding of the electrode film to the polycarbonate at lower temperatures has been shown to be not effective, due to high resistance of the polycarbonate. Polycarbonate resistance is several orders of magnitude higher than that of glass, where the resistance of glass is approximately 20 Ω and the resistance of polycarbonate is approximately 20 kΩ and resistivity is >10¹ Ωcm.

Also, polycarbonate is permeable to air and water. The permeability of polycarbonate means the operational life of an OLED structure with polycarbonate is less than one day, due to oxidation of the Ca layer by air and/or water passing through the polycarbonate and other layers.

In the embodiment illustrated in FIGS. 5 and 6, a first ta-C layer 58 is provided, using the method described above, between a polycarbonate layer 60 and a transparent electrode layer 62. The thickness of the ta-C layer 58 is 30-50 Å, and the deposition parameters (biasing, etc) are controlled to provide a seed layer coating on the polycarbonate layer having a resistivity of between 10⁶ and 10⁹ Ωcm. This has the effect of reducing the resistivity of the polycarbonate layer 60 to between 10⁶ and 10⁹ Ωcm, and thus improves the adhesion with the transparent electrode layer 62. Other layers, in order as per convention, are an organic OLED polymer layer 64, and Ca and Al 66, In this embodiment, a second polymer layer in the form of a second polycarbonate layer 68 is further provided on the Ca and Al layer 66.

The first ta-C layer 58 has the added advantage of reducing the permeability through the polycarbonate layer 60 to the Ca layer by approximately 100 times. It is also preferable, as illustrated in FIG. 5, to further reduce the permeability of the outer polycarbonate layers 60,68 to provided second and third ta-C layers 70, 72 over the outer surface of the first polycarbonate layer 60 and the outer surface of the second polycarbonate layer 68. The second and third ta-C layers 70, 72 can be thicker than the first ta-C layer 58, and are provided in the range of 20-2000 Å. Each of the ta-C layers 58, 70, 72 are provided according to the preferred method. The additional ta-C layers 70, 72, can reduce H₂O permeation from about 30 gm⁻²day⁻¹ to <10 gm⁻²day⁻¹, when applied at a thickness of about 50 Å, and to <0.6 gm⁻²day⁻¹ when applied at a thickness of about 2000 Å. Permeation can be further reduced by several orders of magnitude by using a multi-alternate layered thin polycarbonate/ta-C substrate in place of a single polycarbonate layer with single ta-C layer applied thereto.

As will be apparent from the above OLED example, the present invention has many potential uses as a seed layer to improve adhesion between metal and polymer layers when depositing metal onto plastics or polymers at room and similar temperatures. For example, DVDs and CDs comprise a top most polymer layer with a reflective Al layer immediately therebelow. A ta-C layer may be provided in accordance with the present invention between the Al layer and the polymer to improve the adhesion of the Al when deposited onto the polymer. Similarly, touch screen panels comprise a top most polymer layer with a transparent electrode layer thereon. A ta-C layer may be provided in accordance with the present invention between the electrode layer and the polymer to improve adhesion.

As will also be understood by the skilled addressee, the invention may be further applied to other uses. For example, the reader arm and head of a hard disk drive apparatus can be coated as described above in reference to FIG. 2 to prevent ESD from the reader arm/head to the hard disk. Also, tray and holders used in production and transport of silicon wafers can be coated according to the preferred method of the invention to provide a coating with a resistivity of 10⁶ to 10⁸ Ωcm. This removes the need for carbon fillets which are presently used to reduce the risk of ESD between the tray and holders, and the silicon wafers. Removing the need for carbon fillets has the added advantage of reducing risk of carbon contamination from the fillets on the wafers.

While the invention has been described in reference to its preferred embodiments, it is to be understood that the words which have been used are words of description rather than limitation and that changes may be made to the invention without departing from its scope as defined by the appended claims.

As a summary, the method and apparatus of the present invention provides a substrate coating having a predetermined resistivity is described. The method comprises the steps of providing a substrate to be coated in a vacuum chamber, creating a plasma in the chamber, and depositing ions of the plasma on the substrate to form a ta-C substrate coating. The coating step is stopped when the ta-C substrate coating has the predetermined resistivity. The predetermined resistivity is 10⁵-10¹ Ωcm, and preferably about 10⁶ Ωcm. The substrate may be biased during the method to aid in arriving at the predetermined resistivity. The coating may be employed to reduce the risk of, or prevent electrostatic discharge to or from the substrate, or to provide a seed layer to improve adhesion between the substrate a further coating. Also described are coatings having predetermined resistivities.

What is claimed is:

1. A method of providing a substrate coating having a predetermined resistivity, comprising the steps of:
providing a substrate to be coated in a vacuum chamber;
creating a carbon plasma in the chamber;
depositing ions of the plasma on the substrate to form a ta-C substrate coating; and
stopping the coating step when the ta-C substrate coating has the predetermined resistivity.

2. The method of claim 1 wherein the predetermined resistivity is 10⁵-10⁹ Ωcm.

3. The method of claim 1 wherein the predetermined resistivity is about 10⁶ Ωcm.

4. The method of claim 1 wherein the coating is 5-80 nm in thickness.

5. The method of claim 1 wherein the coating is 20-50 nm in thickness.

6. The method of claim 1 wherein the substrate is biased during the deposition step.

7. The method of claim 6 wherein the substrate is biased in the range from −100V to −3000V.

8. The method of claim 6 wherein the substrate is biased in the range from −500V to −1500V.

9. The method of claim 1 wherein the step of stopping occurs after 50 to 300 seconds has elapsed from the start of the plasma creation step.

10. The method of claim 1 wherein the deposition step is carried out by apparatus in communication with the chamber, the apparatus comprising a carbon target and a power source for supplying power to the target.

11. The method of claim 10 wherein the deposition step is also carried out by a second apparatus in communication with the chamber, the second apparatus comprising a metal target and a power source for supplying power to the metal target, wherein the ta-C substrate coating comprises metal provided by a plasma from the metal target.

12. The method of claim 1 wherein the chamber is evacuated prior to the deposition step, and the substrate is cleaned in the vacuum chamber after the chamber is evacuated and prior to the deposition step.

13. The method of claim 10 wherein the chamber is evacuated prior to the deposition step, and the substrate is cleaned in the vacuum chamber after exposure to the plasma and prior to a step of repressurising the chamber.

14. The method of claim 10 wherein the apparatus is a filtered cathodic vacuum arc apparatus.

15. The method of claim 10 comprising introducing a gas into the vacuum chamber to form a coating on the substrate which is a compound of the gas and ta-C.

16. The method of claim 15 wherein the gas is one of nitrogen, argon, ammonia, oxygen, methane, and ethene (ethylene).

17. The method of claim 1 wherein the substrate is one of or a portion or component of: a fingerprint sensor; an electronic package having an exposed active circuit; memory media; digital memory reader component; an integrated circuit package; or a layer of an organic light emitting diode.

18. A substrate comprising a ta-C coating having a predetermined resistivity of 10⁵-10⁹ Ωcm.

19. The substrate of claim 18 comprising a ta-C coating having a predetermined resistivity of 10⁶ Ωcm.

20. A ta-C coating for a substrate, the coating having a predetermined resistivity of 10⁵-10⁹ Ωcm.

21. The ta-C coating of claim 20 having a predetermined resistivity of 10⁶ Ωcm.

22. A substrate comprising a ta-C coating having a predetermined resistivity of 10⁵-10⁹ Ωcm, wherein the coating is provided by the method of claim 1.

23. Apparatus for providing a coating of ta-C on a substrate, the apparatus comprising:
a vacuum chamber for housing the substrate to be coated;
means for creating a carbon plasma in the chamber; and
control means for actuating the means for creating the carbon plasma, and for stopping the plasma creating means when the ta-C substrate coating has a predetermined resistivity.

24. The apparatus of claim 23 wherein the predetermined resistivity is 10⁵-10⁹ Ωcm.

25. The apparatus of claim 23 wherein the predetermined resistivity is about 10⁶ Ωcm.

26. The apparatus of claim 23 wherein the control means is configured to stop the plasma creating means when the coating is 5-80 nm in thickness.

27. The apparatus of claim 23 wherein the control means is configured to stop the plasma creating means when the coating is 20-50 nm in thickness.

28. The apparatus of claim 23 comprising substrate biasing means for biasing the substrate when the plasma creating means is actuated.

29. The apparatus of claim 28 wherein the substrate biasing means is configured to bias the substrate in the range from −100V to −3000V.

30. The apparatus of claim 28 wherein the substrate biasing means is configured to bias the substrate in the range from −500V to −1500V.

31. The apparatus of claim 23 wherein the plasma creating means is a filtered cathodic vacuum arc apparatus.

32. An organic light emitting diode (OLED) display comprising a plurality of stacked layers, the layers including, in order of stacking:
a first transparent polymer layer;
a ta-C seed layer having a predetermined resistivity;
a transparent electrode film layer;
an organic layer;
one or more metallic layers; and
a second polymer layer.

33. The OLED display of claim 32 wherein the predetermined resistivity is 10⁵-10⁹ Ωcm.

34. The OLED display of claim 32 wherein the ta-C layer is 10-50 Å in thickness.

35. The OLED display of claim 32 wherein the first polymer layer is polycarbonate.

36. The OLED display of claim 32 wherein the transparent electrode film layer is one of ITO or ZnO.

37. The OLED display of claim 32 wherein the one or more metallic layers include Ca and Al.

38. The OLED display of claim 32 comprising a second ta-C layer on a side of the first polymer layer opposed to the side adjacent the first ta-C layer.

39. The OLED display of claim 32 comprising a third ta-C layer on a side of the second polymer layer opposed to the side adjacent the one or more metallic layers.

40. The OLED display of claim 38 wherein the second ta-C layer is 20-500 Å.

41. An organic light emitting diode (OLED) display comprising a plurality of stacked layers, the layers including, in order of stacking:
a first transparent polymer layer;
a ta-C seed layer having a predetermined resistivity;
a transparent electrode film layer;
an organic layer;
one or more metallic layers; and
a second polymer layer, wherein the ta-C layer is provided by the method of claim 1.
